(19) United States
(12) Patent Application Publication
(10) Pub. No.: US 2010/0122138 A1
(43) Pub. Date: May 13, 2010

(54) Radio Communication Device and Radio Communication Method

(75) Inventors: Akihiko Nishio, Kanagawa (JP); Kenichi Kuri, Kanagawa (JP)

Correspondence Address: Dickinson Wright PLLC;James E. Ledbetter, Esq., International Square, 1875 Eye Street, N.W., Suite 1200, Washington, DC, 20006, US

(73) Assignee: Panasonic Corporation, Osaka (JP)

(21) Appl. No.: 12/596,128

(22) PCT Filed: Apr. 16, 2008
(86) PCT No.: PCT/JP2008/001001

§ 371 Date: Oct. 15, 2009

(30) Foreign Application Priority Data
Apr. 17, 2007 (JP) 2007-108572

(51) Int. Cl. H03M 13/05; G06F 11/10

(52) U.S. Cl. 714/752; 714/E11.032

(57) ABSTRACT

Provided is a radio communication device which can always obtain an optimal error ratio characteristic in HARQ using the LDPC code as an error correction code. The device includes: a rearrangement unit (101) which rearranges a transmission bit string according to a column weight of an inspection matrix; an LDPC encoding unit (102) which performs an LDPC encoding based on the inspection matrix on the transmission bit string so as to obtain an LDPC codeword A and performs an LDPC encoding based on the inspection matrix on the bit string subjected to the rearrangement and inputted from the rearrangement unit (101) so as to obtain an LDPC codeword B; and a HARQ unit (103) which selects the LDPC codeword A or the LDPC codeword B in accordance with the number of transmissions of the LDPC codeword.

### TECHNICAL FIELD

The present invention relates to a radio communication apparatus and radio communication method.

### BACKGROUND ART

In recent years, multimedia communication such as data communication and video communication has continued to increase in popularity. Therefore, data sizes are expected to increase more in the future, and growing demands for higher-speed data rates for mobile communication services are also anticipated.

Therefore, the ITU-R (International Telecommunication Union Radio Communication Sector) has studied a fourth-generation mobile communication system called “IMT-Advanced,” and an LDPC (Low-Density Parity-Check) code is becoming a focus of attention as an error correction code for realizing a downlink rate of a maximum of 1 Gbps. The use of an LDPC code as an error correcting code allows decoding processing to be paralleled, and can thereby increase the speed of decoding processing compared to a turbo code which requires repeated serial decoding processing.

LDPC encoding is performed based on a parity check matrix in which a large number of ‘0’s and a small number of ‘1’s are allocated. A radio communication apparatus on the transmitting side encodes a transmission bit sequence based on a parity check matrix to obtain an LDPC codeword comprising systematic bits and parity bits. Furthermore, a radio communication apparatus on the receiving side decodes received data by iteratively executing passing of the likelihood of each bit in the row direction of the parity check matrix and in the column direction of the parity check matrix, obtains a received bit sequence. Here, the number of ‘1’s included in each column of the parity check matrix is referred to as a “column degree” and the number of ‘1’s included in each row of the parity check matrix is referred to as a “row degree.” Furthermore, the parity check matrix can be represented by a Tanner graph which is a two-part graph comprising rows and columns. In the Tanner graph, each row of the parity check matrix is referred to as a “check node,” while each column of the parity check matrix is referred to as a “variable node.” Variable nodes and check nodes of the Tanner graph are connected according to the allocation of ‘1’s in the parity check matrix and the radio communication apparatus on the receiving side decodes received data by iteratively executing passing of likelihood between the connected nodes, and obtains a received bit sequence.

Furthermore, there is HARQ (Hybrid ARQ) combining ARQ (Automatic Repeat reQuest) and error correcting code. In HARQ, the radio communication apparatus on the receiving side feeds back an ACK (Acknowledgment) signal when there is no error in the received data and a NACK (Negative Acknowledgment) signal when there are errors, to the radio communication apparatus on the transmitting side as a response signal. Furthermore, the radio communication apparatus on the receiving side combines data retransmitted from the radio communication apparatus on the transmitting side and erroneous data received in the past, and performs error correcting decoding on the combined data. By this means, it is possible to improve an SINR, improve coding gains and decode received data through a fewer number of retransmissions than a normal ARQ.

HARQ includes a CC (Chase Combining) scheme and IR (Incremental Redundancy) scheme. In the CC scheme, a whole codeword is retransmitted, while, in the IR scheme, a codeword is divided into a plurality of redundancy versions (hereinafter referred to as “RV's”) and these plurality of RV's are sequentially transmitted upon a retransmission.

Here, a conventional technique of HARQ using an LDPC code as an error correcting code includes allocating bits of a larger column degree of the parity check matrix (i.e. bits in which errors are less likely to occur) in communication resources of poorer channel quality (i.e. communication resources in which errors are likely to occur) (e.g., see Patent Document 1).

### Patent Document 1: Japanese Patent Application Laid-Open No. 2005-277784

### DISCLOSURE OF INVENTION

### Problems to be Solved by the Invention

However, when bits of an LDPC codeword are allocated in communication resources according to a column degree of the parity check matrix as in the case of the above-described conventional technique, even if bits allocated in communication resources of poor channel quality are retransmitted many times, the radio communication apparatus on the receiving side can receive only bits of deteriorated quality, and therefore the error rate performance may not improve at all.

It is therefore an object of the present invention to provide a radio communication apparatus and radio communication method that can always obtain optimum error rate performance in HARQ using an LDPC code as an error correcting code.

### Means for Solving the Problem

The present invention adopts a configuration including: a rearrangement section that rearranges a first bit sequence to generate a second bit sequence; an encoding section that performs LDPC encoding using a parity check matrix on the first bit sequence to obtain a first codeword and performs the LDPC encoding using the parity check matrix on the second bit sequence to obtain a second codeword; and a selection section that selects one of the first codeword and the second codeword.

### ADVANTAGEOUS EFFECTS OF INVENTION

According to the present invention, it is possible to always obtain optimum error rate performance in HARQ using an LDPC code as an error correcting code.

### BRIEF DESCRIPTION OF DRAWINGS

FIG. 1 is a block diagram of a radio communication apparatus on the transmitting side according to Embodiment 1 of the present invention;

FIG. 2 is a parity check matrix according to Embodiment 1 of the present invention;

FIG. 3 is a Tanner graph according to Embodiment 1 of the present invention;

FIG. 4 illustrates rearrangement processing according to Embodiment 1 of the present invention;

FIG. 5 illustrates LDPC encoding processing according to Embodiment 1 of the present invention;

FIG. 6 illustrates transmission processing according to Embodiment 1 of the present invention;

FIG. 7 is a block diagram of a radio communication apparatus on the receiving side according to Embodiment 1 of the present invention;

FIG. 8 illustrates combination processing according to Embodiment 1 of the present invention;

FIG. 9 illustrates an RV configuration according to Embodiment 2 of the present invention;

FIG. 10 illustrates a transmission rule according to Embodiment 2 of the present invention;

FIG. 11 illustrates transmission processing according to Embodiment 2 of the present invention;

FIG. 12 is a block diagram of a radio communication apparatus on the receiving side according to Embodiment 2 of the present invention;

FIG. 13 illustrates combination processing according to Embodiment 2 of the present invention;

FIG. 14 illustrates a transmission rule according to Embodiment 3 of the present invention;

FIG. 15 illustrates transmission processing according to Embodiment 3 of the present invention;

FIG. 16 is a block diagram of a radio communication apparatus on the receiving side according to Embodiment 4 of the present invention; and

FIG. 17 illustrates combination processing according to Embodiment 4 of the present invention.

### BEST MODE FOR CARRYING OUT THE INVENTION

Hereinafter, embodiments of the present invention will be explained in detail with reference to the accompanying drawings. In the following explanations, in each column of a parity check matrix or each variable node of a Tanner graph, a part corresponding to a systematic bit will be referred to as a “systematic bit position” and a part corresponding to a parity bit will be referred to as a “parity bit position.”

### Embodiment 1

The present embodiment will explain HARQ of a CC scheme using an LDPC code as an error correcting code.

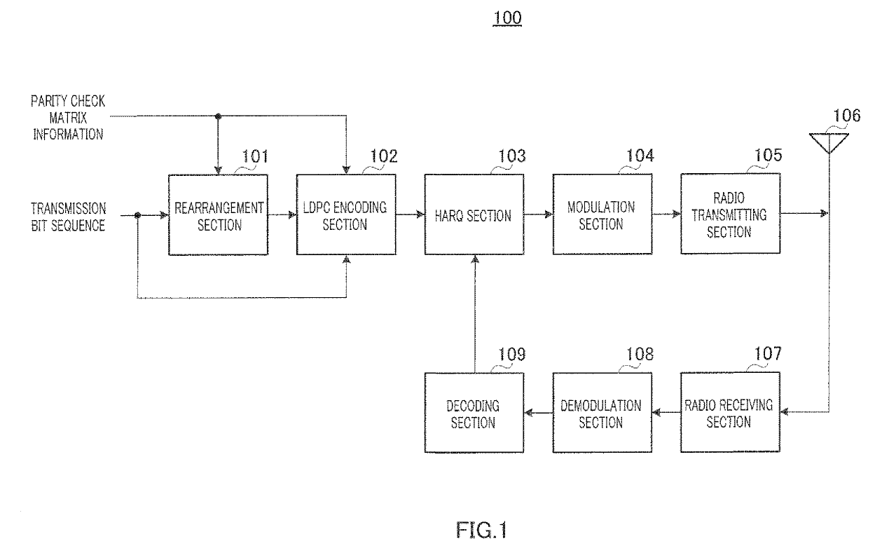

FIG. 1 shows the configuration of radio communication apparatus 100 on the transmitting side according to the present embodiment.

In radio communication apparatus 100 on the transmitting side, rearrangement section 101 receives as input a transmission bit sequence and parity check matrix information. Rearrangement section 101 rearranges the transmission bit sequence based on column degrees of a parity check matrix and outputs the rearranged bit sequence to LDPC encoding section 102. Rearrangement processing in rearrangement section 101 will be described later in detail.

LDPC encoding section 102 receives as input the transmission bit sequence and parity check matrix information. LDPC encoding section 102 performs LDPC encoding on the transmission bit sequence based on the parity cheek matrix to obtain an LDPC codeword A comprising systematic bits and parity bits. Furthermore, LDPC encoding section 102 performs LDPC encoding on the bit sequence received as input from rearrangement section 101 based on the parity check matrix to obtain an LDPC codeword B comprising systematic bits and parity bits. LDPC encoding section 102 outputs LDPC codeword A and LDPC codeword B to HARQ section 103.

HARQ section 103 stores LDPC codeword A and LDPC codeword B received as input from LDPC encoding section 102, selects one of LDPC codeword A and LDPC codeword B according to the number of transmissions of LDPC codeword, and outputs the selected LDPC codeword to modulation section 104. To be more specific, HARQ section 103 selects LDPC codeword A at a first transmission (initial transmission) and outputs LDPC codeword A to modulation section 104. Furthermore, when a NACK signal is received as input from decoding section 109, that is, at a second transmission (first retransmission), HARQ section 103 selects LDPC codeword B and outputs LDPC codeword B to modulation section 104. Furthermore, when an ACK signal is received as input from decoding section 109, HARQ section 103 stops outputting the LDPC codeword to modulation section 104 and discards the stored LDPC codewords. The selection processing by HARQ section 103 will be described later in detail.

Modulation section 104 modulates the LDPC codeword received as input from HARQ section 103 to generate a data symbol, and outputs the data symbol to radio transmitting section 105.

Radio transmitting section 105 performs transmission processing such as D/A conversion, amplification and up-conversion on the data symbol and transmits the result from antenna 106 to a radio communication apparatus on the receiving side.

On the other hand, radio receiving section 107 receives a control signal transmitted from the radio communication apparatus on the receiving side via antenna 106, performs reception processing such as down-conversion and A/D conversion on the control signal and outputs the result to demodulation section 108. This control signal includes a response signal (ACK signal or NACK signal).

Demodulation section 108 demodulates the control signal and outputs the demodulated control signal to decoding section 109.

Decoding section 109 decodes the control signal and outputs the response signal included in the control signal to HARQ section 103.

Next, the rearrangement processing in rearrangement section 101 will be explained in detail.

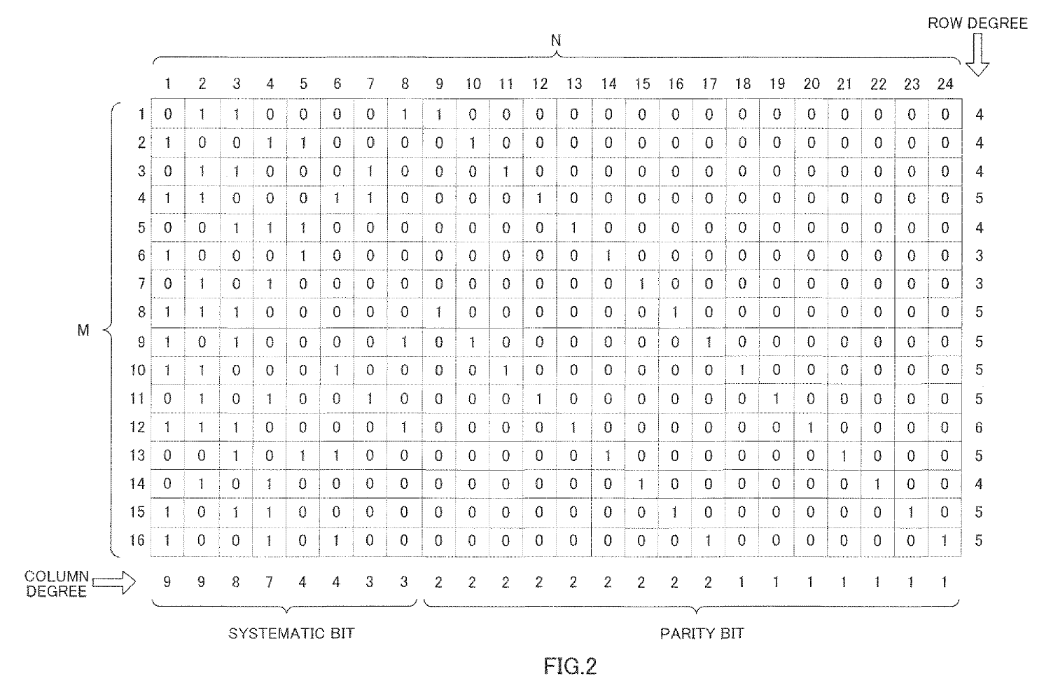

FIG. 2 shows a parity check matrix of 16 rows×24 columns as an example. Thus, the parity check matrix is expressed by a matrix of M rows×N columns and comprises ‘0’s and ‘1’s.

Furthermore, columns of the parity check matrix corresponds to bits of the LDPC codeword. That is, when LDPC encoding is performed based on the parity check matrix shown in FIG. 2, a 24-bit LDPC codeword is obtained.

Furthermore, in the parity check matrix shown in FIG. 2, the column degree of the first column is equal to the number of ‘1’s on the first column, that is, nine, and the column degree of the second column is equal to the number of ‘1’s on the second column, that is, nine. Therefore, in the 24-bit LDPC codeword, the column degree of the first bit is nine and the column degree of the second bit is nine. The same applies to the third column to the twenty-fourth column.

Likewise, in the parity check matrix shown in FIG. 2, the row degree of the first row is equal to the number of ‘1’s on the first row, that is, four and the row degree of the second row is equal to the number of ‘1’s on the second row, that is, four. The same applies to the third row to sixteenth row.

Furthermore, the parity check matrix shown in FIG. 2 can be represented by a Tanner graph comprising the rows and columns of the parity check matrix.

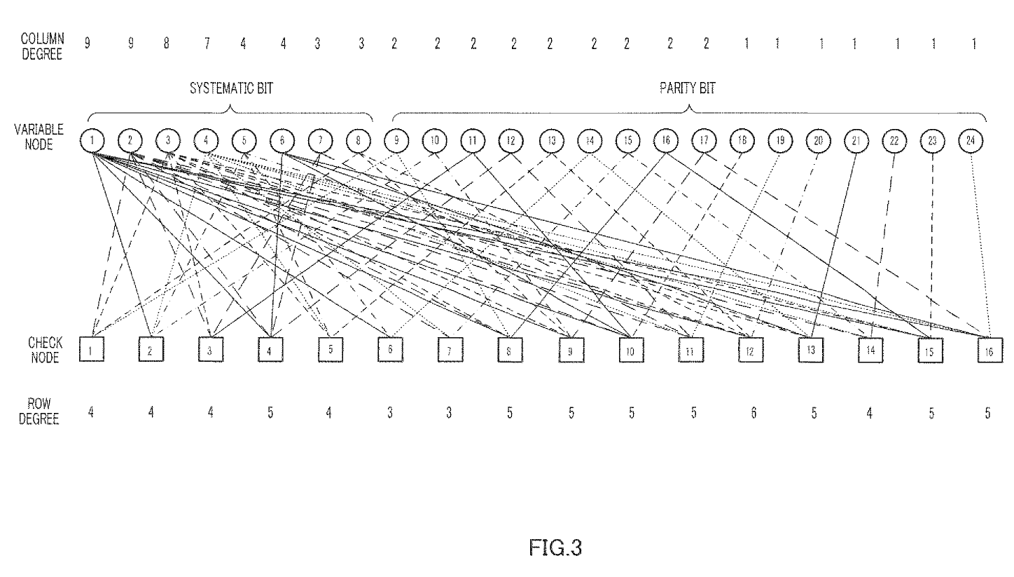

FIG. 3 shows a Tanner graph corresponding to the parity check matrix in FIG. 2. The Tanner graph comprises check nodes corresponding to the rows of the parity check matrix and variable nodes corresponding to the columns of the parity check matrix. That is, the Tanner graph corresponding to the parity check matrix of 16 rows×24 columns is a two-part graph comprising sixteen check nodes and twenty-four variable nodes.

Furthermore, the variable nodes of the Tanner graph corresponds to the bits of the LDPC codeword.

Furthermore, the variable nodes and the check nodes of the Tanner graph are connected according to the arrangement of ‘1’s on the parity check matrix.

This will be explained in detail with reference to the variable nodes. Variable node 1 in the Tanner graph shown in FIG. 3 corresponds to the first column (N=1) of the parity check matrix shown in FIG. 2.

Furthermore, the column degree of the first column of the parity check matrix is nine and the rows in which ‘1’s are allocated on the first column are the second row, fourth row, sixth row, eighth row, ninth row, tenth row, twelfth row, fifteenth row and sixteenth row. Therefore, variable node 1 is connected to nine nodes of check node 2, check node 4, check node 6, check node 8, check node 9, check node 10, check node 12, check node 15 and check node 16. Similarly, variable node 2 of the Tanner graph corresponds to the second column (N=2) of the parity check matrix. Furthermore, the column degree of the second column of the parity check matrix is nine and the rows in which ‘1’s are allocated on the second column are first row, third row, fourth row, seventh row, eighth row, tenth row, eleventh row, twelfth row and fourteenth row. Therefore, variable node 2 is connected to nine nodes of check node 1, check node 3, check node 4, check node 7, check node 8, check node 10, check node 11, check node 12 and check node 14. The same applies to variable node 3 to variable node 24.

Similarly, when the above is explained in detail with reference to the check nodes, check node 1 of the Tanner graph shown in FIG. 3 corresponds to the first row (M=1) of the parity check matrix shown in FIG. 2. Also, the row degree of the first row of the parity check matrix is four and the columns in which ‘1’s are allocated on the first row are the second column, third column, eighth column and ninth column. Therefore, check node 1 is connected to four nodes of variable node 2, variable node 3, variable node 8 and variable node 9. Likewise, check node 2 of the Tanner graph corresponds to the second row (M=2) of the parity check matrix. Also, the row degree of the second row of the parity check matrix is four and the columns in which ‘1’s are allocated on the second row are the first column, fourth column, fifth column and 10th column. Therefore, check node 2 is connected to four nodes of variable node 1, variable node 4, variable node 5 and variable node 10. The same applies to check node 3 to check node 16.

By this means, the variable nodes and check nodes in the Tanner graph are connected according to the allocation of ‘1’s in the parity check matrix. That is, the number of check nodes connected to variable nodes of the Tanner graph is equal to the column degree of each column of the parity check matrix. Furthermore, a check node to which each variable node of the Tanner graph is connected is the check node corresponding to a row in which ‘1’ is allocated in each column of the parity check matrix. Likewise, the number of variable nodes connected to each check node of the Tanner graph is equal to the row degree of each row of the parity check matrix. Furthermore, a variable node to which each check node of the Tanner graph is connected is the variable node corresponding to a column in which ‘1’ is allocated in each row of the parity check matrix.

The radio communication apparatus on the receiving side decodes received data by performing mutual passing of likelihoods between variable nodes via check nodes, and iteratively performing updating of the likelihood of each variable node. Thus, a variable node connected to a greater number of check nodes (i.e. variable node having a larger column degree) has a greater number of passing of likelihood from other variable nodes. Therefore, a variable node connected to a greater number of check nodes has a greater number of likelihoods received via the connected check nodes, and therefore has a greater effect of likelihood improvement.

Therefore, when rearranging a transmission bit sequence, the present embodiment allocates bits having a smaller effect of likelihood improvement, that is, bits at systematic bit positions corresponding to variable nodes connected to a smaller number of check nodes, to systematic bit positions corresponding to variable nodes connected to a greater number of check nodes. In this way, bits with larger column degrees at the initial transmission have smaller column degrees at a retransmission and bits with smaller column degrees at an initial transmission have larger column degrees at a retransmission. Therefore, a retransmission equalizes the effect of likelihood improvement between bits of a transmission bit sequence and equalizes error rates between bits of a decoded bit sequence. Thus, the present embodiment preferentially supplements likelihoods of bits having smaller effects of likelihood improvement by rearranging the transmission bit sequence, thereby improving the error rate performance of each bit of the decoded bit sequence to a uniform level.

Therefore, rearrangement section 101 rearranges the transmission bit sequence by allocating bits at systematic bit positions corresponding to variable nodes connected to a fewer number of check nodes (i.e., variable nodes having smaller column degrees) in the transmission bit sequence, to systematic bit positions corresponding to variable nodes connected to a greater number of check nodes (i.e., variable nodes having larger column degrees).

The present embodiment will be explained in detail. In the following explanations, suppose the transmission bit sequence length is eight bits. Therefore, when LDPC encoding section 102 performs LDPC encoding on a 8-bit transmission bit sequence based on the parity check matrix shown in FIG. 2, an LDPC codeword with N=24 bits comprised of eight systematic bits and sixteen parity bits.

First, rearrangement section 101 compares column degrees among the first column to eighth column (i.e. variable node 1 to variable node 8 in the Tanner graph shown in FIG. 3) corresponding to systematic bit positions of the parity check matrix shown in FIG. 2. That is, rearrangement section 101 compares column degree nine of the first column (the number of connections (nine connections) to check nodes at variable node 1), column degree nine of the second column (the number of connections (nine connections) to cheek nodes at variable node 2), column degree eight of the third column (the number of connections (eight connections) to check nodes at variable node 3), column degree seven of the fourth column (the number of connections (seven connections) to check nodes at variable node 4), column degree four of the fifth column (the number of connections (four connections) to check nodes at variable node 5), column degree four of the sixth column (the number of connections (four connections) to check nodes at variable node 6), column degree three of the seventh column (the number of connections (three connections) to check nodes at variable node 7) and column degree three of the eighth column (the number of connections (three connections) to check nodes at variable node 8). Therefore, the column degrees in the first column to eighth column (i.e. variable node 1 to variable node 8) are in descending order of magnitude from the first column (variable node 1) to eighth column (variable node 8).

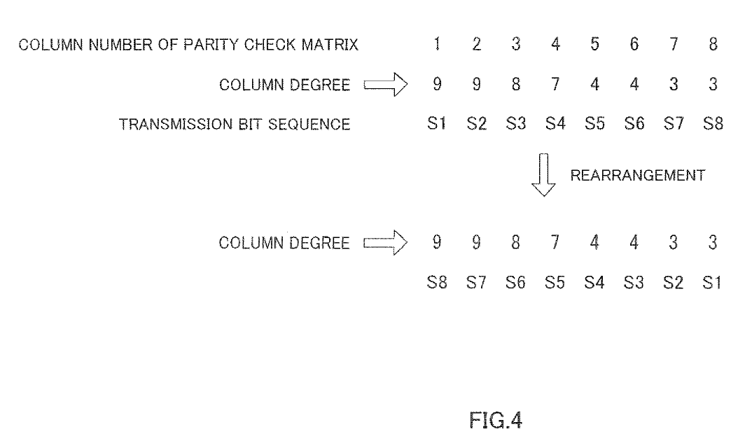

Rearrangement section 101 then rearranges eight transmission bits S1 to S8 as shown in FIG. 4 according to the order of the column degrees of systematic bit positions. That is, rearrangement section 101 allocates S8 at the systematic bit position of the first column (variable node 1), allocates S7 at the systematic bit position of the second column (variable node 2), allocates S6 at the systematic bit position of the third column (variable node 3), allocates S5 at the systematic bit position of the fourth column (variable node 4), allocates S4 at the systematic bit position of the fifth column (variable node 5), allocates S3 at the systematic bit position of the sixth column (variable node 6), allocates S2 at the systematic bit position of the seventh column (variable node 7) and allocates S1 at the systematic bit position of the eighth column (variable node 8).

That is, as shown in FIG. 4, rearrangement section 101 rearranges an 8-bit transmission bit sequence comprised of S1, S2, S3, S4, S5, S6, S7 and S8 and outputs an 8-bit sequence comprised of S8, S7, S6, S5, S4, S3, S2 and S1 to LDPC encoding section 102.

Next, selection processing by HARQ section 103 will be explained in detail.

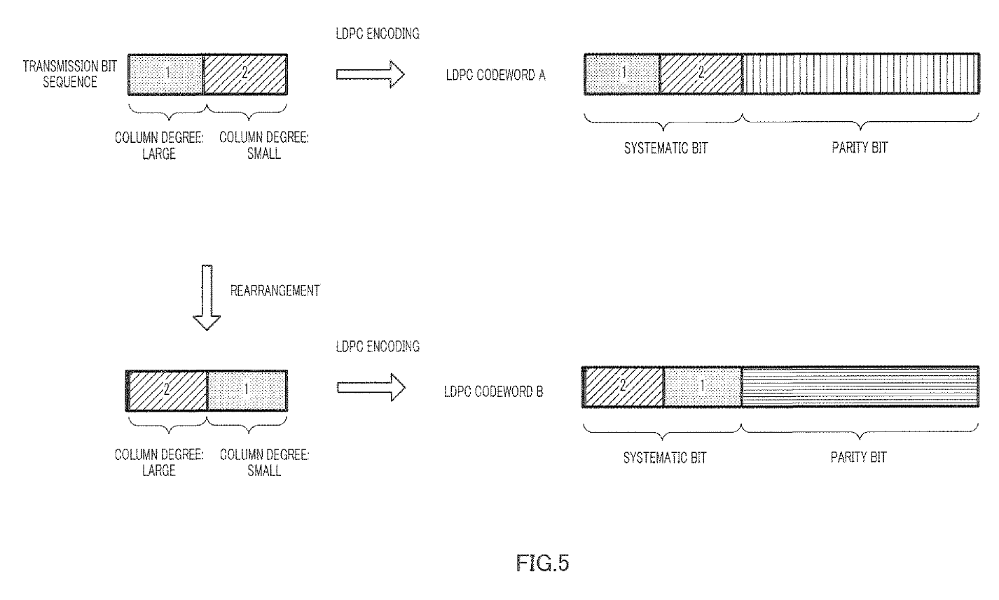

In the following explanation, as shown in FIG. 5, suppose bit sequence 1 is allocated to a systematic bit position with a larger column degree and bit sequence 2 is allocated to a systematic bit position with a smaller column degree in the transmission bit sequence for ease of explanation. That is, the transmission bit sequence is comprised of bit sequence 1 and bit sequence 2 in order. For example, in the transmission bit sequences S1 to S8 shown in FIG. 4, bit sequence 1 shown in FIG. 5 is comprised of S1 to S4 and bit sequence 2 is comprised of S5 to S8. For the transmission hit sequence shown in FIG. 5, as described above, rearrangement section 101 allocates the bits of bit sequence 2 to systematic bit positions with larger column degrees and allocates the bits of bit sequence 1 to systematic bit positions with smaller column degrees. By this means, it is possible to produce a bit sequence comprised of bit sequence 2 and bit sequence 1 in order. As shown in FIG. 5, LDPC encoding section 102 then performs LDPC encoding on the transmission bit sequence based on the parity check matrix to obtain an LDPC codeword A and also performs LDPC encoding on the rearranged bit sequence based on the parity check matrix to obtain an LDPC codeword B.

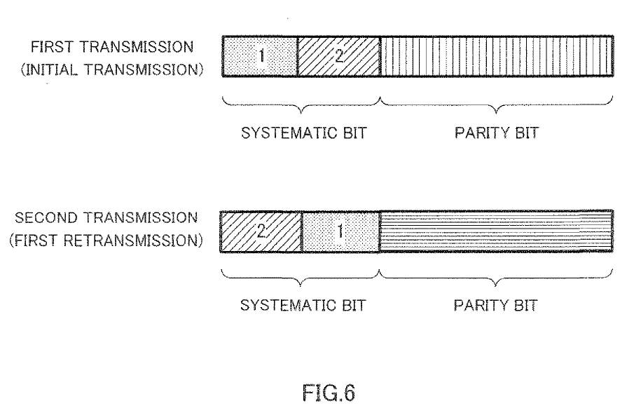

HARQ section 103 selects one of LDPC codeword A and LDPC codeword B according to the number of transmissions of LDPC codeword. To be more specific, as shown in FIG. 6, HARQ section 103 selects LDPC codeword A at the first transmission (initial transmission) and outputs LDPC codeword A to modulation section 104. On the other hand, upon receiving as input a NACK signal input from decoding section 109, that is, at the second transmission (first retransmission), HARQ section 103 selects LDPC codeword B and outputs LDPC codeword B to modulation section 104.

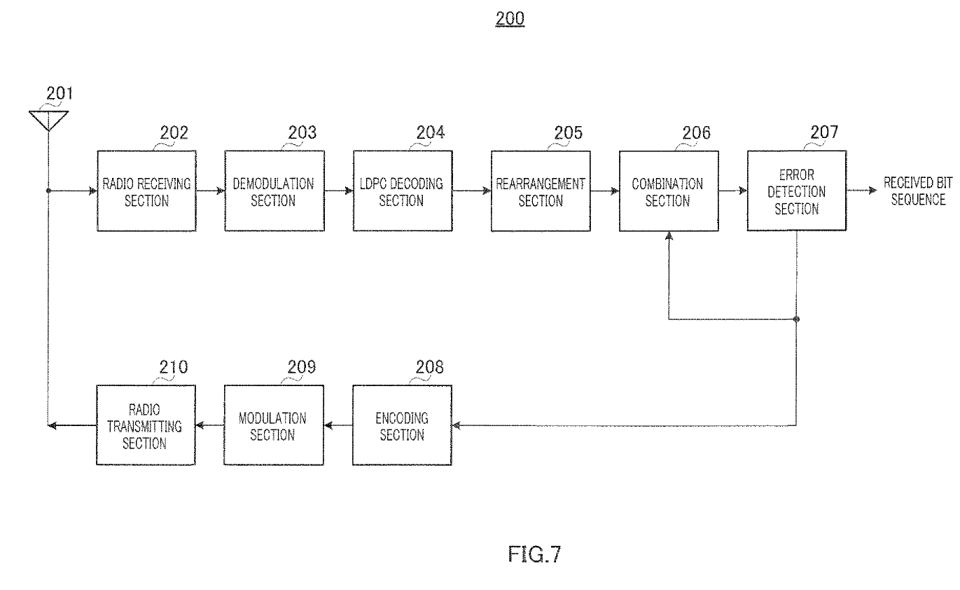

Next, the radio communication apparatus on the receiving side according to the present embodiment will be explained. FIG. 7 shows the configuration of radio communication apparatus 200 on the receiving side according to the present embodiment.

In radio communication apparatus 200 on the receiving side, radio receiving section 202 receives a data symbol transmitted from radio communication apparatus 100 on the transmitting side (FIG. 1) via antenna 201, performs reception processing such as down-conversion and A/D conversion on the received signal and outputs the result to demodulation section 203.

Demodulation section 203 demodulates the data symbol to obtain received data and outputs the received data to LDPC decoding section 204.

LDPC decoding section 204 performs LDPC decoding on the received data received as input from demodulation section 203, based on the same parity check matrix as the parity check matrix used in LDPC encoding section 102 (FIG. 1), to obtain a decoded bit sequence. LDPC decoding section 204 then outputs the decoded bit sequence to rearrangement section 205.

Upon receiving first transmission data (initial transmission data), rearrangement section 205 outputs the decoded bit sequence received as input from LDPC decoding section 204 as is to combination section 206. On the other hand, upon receiving second transmission data (first retransmission data), rearrangement section 205 rearranges the decoded bit sequence based on the parity check matrix and outputs the rearranged bit sequence to combination section 206.

Upon receiving first transmission data (initial transmission data), combination section 206 stores the decoded bit sequence received as input from rearrangement section 205 and outputs the decoded bit sequence to error detection section 207. On the other hand, upon receiving second transmission data (first retransmission data), that is, upon receiving as input a NACK signal from error detection section 207, combination section 206 combines the decoded bit sequence received as input from rearrangement section 205 and the stored bit sequence to generate a combined bit sequence, stores the combined bit sequence and outputs the combined bit sequence to error detection section 207. Furthermore, when an ACK signal is received as input from error detection section 207, that is, when there is no error in the decoded bit sequence or the combined bit sequence outputted from combination section 206, combination section 206 discards the stored bit sequence.

Error detection section 207 performs an error detection on the bit sequence received as input from combination section 206. When the error detection result shows that the decoded bit sequence or combined bit sequence contains an error, error detection section 207 generates a NACK signal as a response signal and outputs the NACK signal to combination section 206 and encoding section 208, whereas, when there is no error in the decoded bit sequence or combined bit sequence, error detection section 207 generates an ACK signal as a response signal and outputs the ACK signal to combination section 206 and encoding section 208. Furthermore, when there is no error in the decoded bit sequence or combined bit sequence, error detection section 207 outputs the decoded bit sequence or combined bit sequence as a received bit sequence.

Encoding section 208 encodes the response signal received as input from error detection section 207 and outputs the encoded response signal to modulation section 209.

Modulation section 209 modulates the response signal to generate a control signal and outputs the control signal to radio transmitting section 210.

Radio transmitting section 210 performs transmission processing such as D/A conversion, amplification and up-conversion on the control signal and transmits the result from antenna 201 to radio communication apparatus 100 on the transmitting side (FIG. 1).

Next, the operations of radio communication apparatus 200 on the receiving side having the above configuration will be explained in detail.

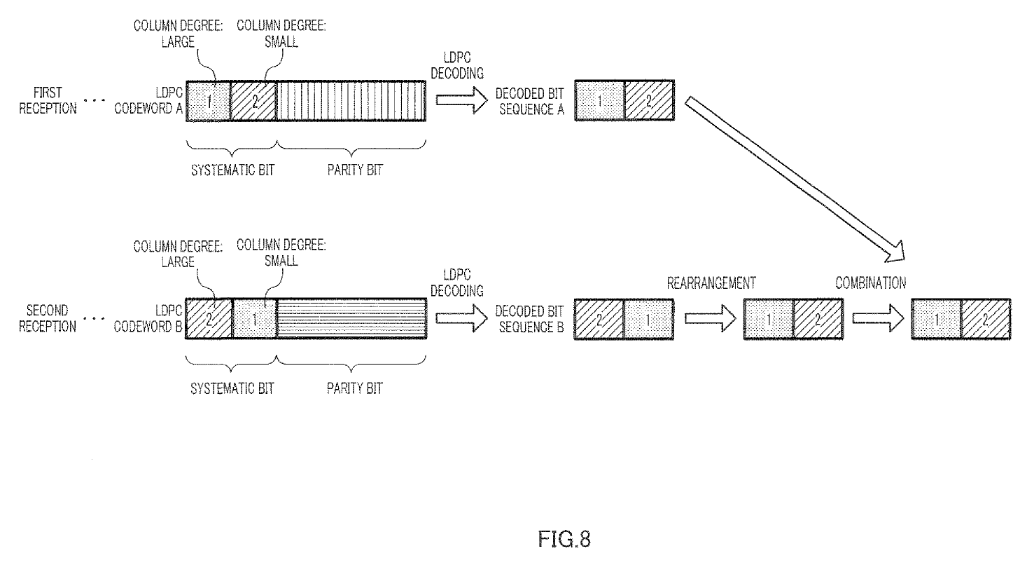

As shown in FIG. 8, upon receiving first transmission data (initial transmission data), that is, upon receiving LDPC codeword A shown in FIG. 5 above, LDPC decoding section 204 performs LDPC decoding on LDPC codeword A to obtain a decoded bit sequence A comprised of bit sequence 1 and bit sequence 2 in order. Here, each bit of bit sequence 1 in LDPC codeword A is a systematic bit with a large column degree and each bit of bit sequence 2 is a systematic bit with a small column degree. Therefore, in the decoded bit sequence A obtained, the effect of likelihood improvement of each bit of bit sequence 1 is large, while the effect of likelihood improvement of each bit of bit sequence 2 is small.

Next, upon receiving second transmission data (first retransmission data), that is, LDPC codeword B shown in FIG. 5 above, LDPC decoding section 204 performs LDPC decoding on LDPC codeword B to obtain a decoded bit sequence B comprised of bit sequence 2 and bit sequence 1 in order. Here, each bit of bit sequence 2 in LDPC codeword B is a systematic bit with a large column degree, while each bit of hit sequence 1 is a systematic bit with a small column degree. Therefore, in the decoded bit sequence B obtained, the effect of likelihood improvement of each bit of bit sequence 2 is large, while the effect of likelihood improvement of each bit of bit sequence 1 is small.

Rearrangement section 205 rearranges the decoded bit sequence B in the reverse order as shown in FIG. 8. By this means, rearrangement section 205 generates a bit sequence with the same arrangement as that of the decoded bit sequence at the time of reception of the first transmission data (initial transmission data), that is, rearrangement section 205 generates a bit sequence comprised of bit sequence 1 and bit sequence 2 in order as shown in FIG. 8.

As shown in FIG. 8, combination section 206 combines the decoded bit sequence obtained upon receiving the first transmission data (initial transmission data) and the bit sequence obtained upon receiving the second transmission data (first retransmission data) to obtain a combined bit sequence. That is, combination section 206 combines bit sequence 1 having a large effect of likelihood improvement in the first transmission data (initial transmission data) and bit sequence 1 having a small effect of likelihood improvement in the second transmission data (first retransmission data). Likewise, combination section 206 combines bit sequence 2 having a small effect of likelihood improvement in the first transmission data (initial transmission data) and bit sequence 2 having a large effect of likelihood improvement in the second transmission data (first retransmission data). By this means, the likelihood of the bit sequence having a small effect of likelihood improvement in the first transmission data (initial transmission data) can be supplemented by the second transmission data (first retransmission data), thereby equalizing error rates to the same level among bits of the combined bit sequence obtained.

Thus, according to the present embodiment, when an LDPC code is used in HARQ of a CC scheme, in the transmission bit sequence, the radio communication apparatus on the transmitting side performs LDPC encoding by allocating bits having small column degrees and small effects of likelihood improvement at a first transmission to systematic bit positions with large column degrees at a second transmission, and by allocating bits having large column degrees and large effects of likelihood improvement at the first transmission to systematic bit positions with small column degrees at the second transmission. By this means, with the radio communication apparatus on the receiving side, the likelihood of systematic bits having small column degrees and having high error probability upon receiving first transmission data can be improved with high priority upon receiving second transmission data. It is thereby possible to equalize the effects of likelihood improvement of all systematic bits and improve error rate performance of all systematic bits to a uniform level. That is, according to the present embodiment, it is possible to obtain optimum error rate performance.

### Embodiment 2

The present embodiment will explain HARQ of an IR scheme using an LDPC code as an error correcting code.

First, radio communication apparatus 100 on the transmitting side according to the present embodiment will be explained. Explanation of the same configuration and operations as in Embodiment 1 will be omitted.

HARQ section 103 shown in FIG. 1 extracts parity bits of an LDPC codeword, constitutes a plurality of RV's and outputs the RV's to modulation section 104. To be more specific, HARQ section 103 outputs all systematic bits included in LDPC codeword A to modulation section 104 at the first transmission (initial transmission), selects one RV and outputs the RV to modulation section 104. Furthermore, HARQ section 103 selects one RV and outputs the RV to modulation section 104 at the second and subsequent transmissions (retransmissions). Selection processing in HARQ section 103 will be described later in detail.

Modulation section 104 modulates the systematic bits and RV of LDPC codeword A received as input from HARQ section 103 at the first transmission (initial transmission), to generate data symbols and outputs the data symbols to radio transmitting section 105. Furthermore, modulation section 104 modulates the RV received as input from HARQ section 103 at the second and subsequent transmissions (retransmissions), to generate data symbols and outputs the data symbols to radio transmitting section 105.

Next, the selection processing in HARQ section 103 will be explained in detail.

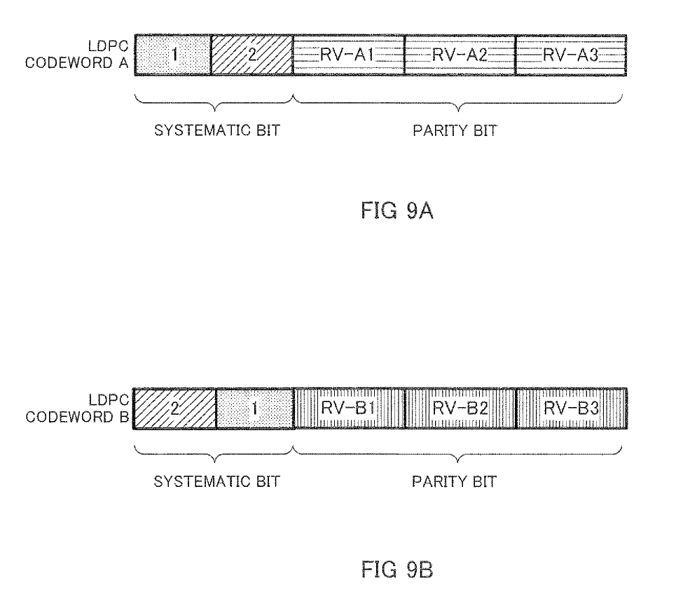

Here, as shown in FIG. 9A, HARQ section 103 according to the present embodiment divides parity bits of LDPC codeword A shown in FIG. 5 into three portions of RV-A1, RV-A2 and RV-A3. Likewise, as shown in FIG. 9B, HARQ section 103 divides parity bits of LDPC codeword B shown in FIG. 5 into three portions of RV-B1, RV-B2 and RV-B3.

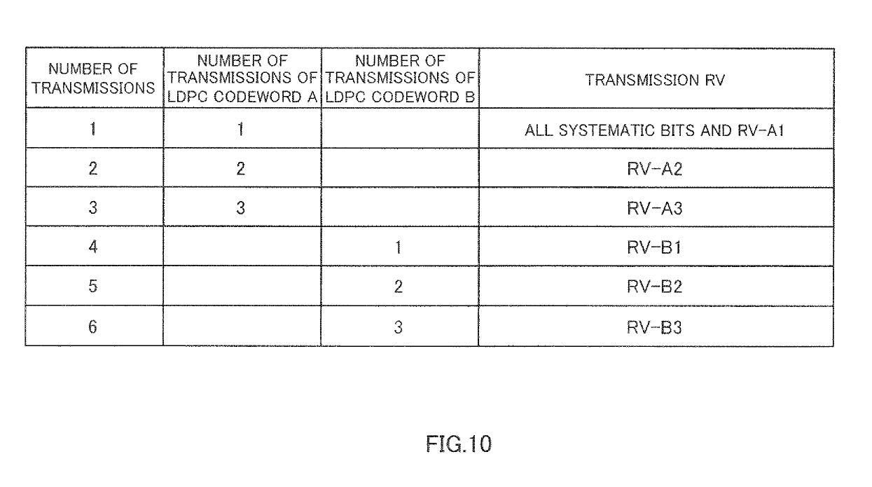

Furthermore, after all parity bits included in LDPC codeword A are transmitted, HARQ section 103 selects only parity bits of LDPC codeword B. To be more specific, HARQ section 103 selects all parity bits included in LDPC codeword A by selecting RV-A1 to RV-A3 in order by the third transmission (second retransmission) according to the transmission rule shown in FIG. 10. Furthermore, HARQ section 103 selects an RV comprised of parity bits of LDPC codeword B at the fourth and subsequent transmissions (third and subsequent retransmissions), that is, RV-B1, RV-B2 and RV-B3 in order.

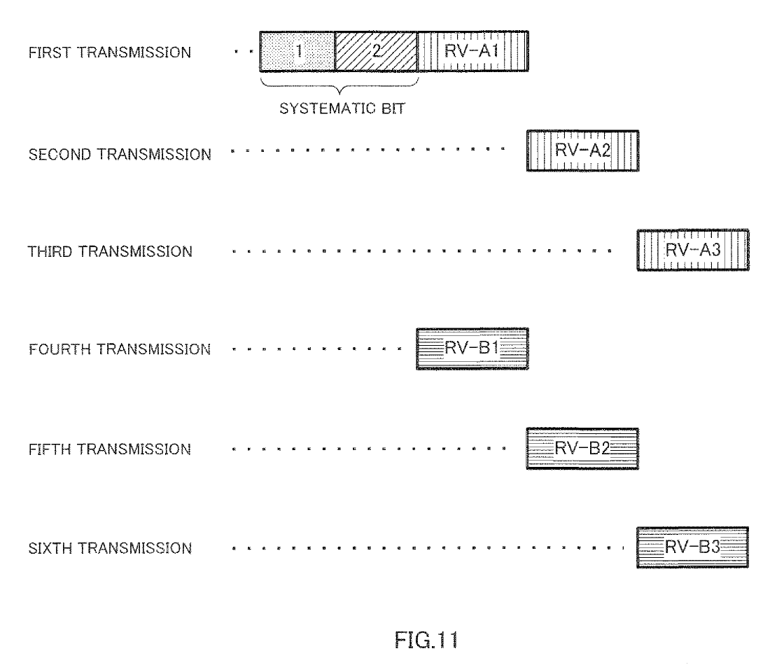

Therefore, as shown in FIG. 11, HARQ section 103 outputs an LDPC codeword comprised of systematic bits and RV-A1 to modulation section 104 at the first transmission (initial transmission), outputs RV-A2 to modulation section 104 at the second transmission (first retransmission) and outputs RV-A3 to modulation section 104 at the third transmission (second retransmission). Furthermore, HARQ section 103 outputs RV-B1 to modulation section 104 at the fourth transmission (third retransmission), outputs RV-B2 to modulation section 104 at the fifth transmission (fourth retransmission) and outputs RV-B3 to modulation section 104 at the sixth transmission (fifth retransmission).

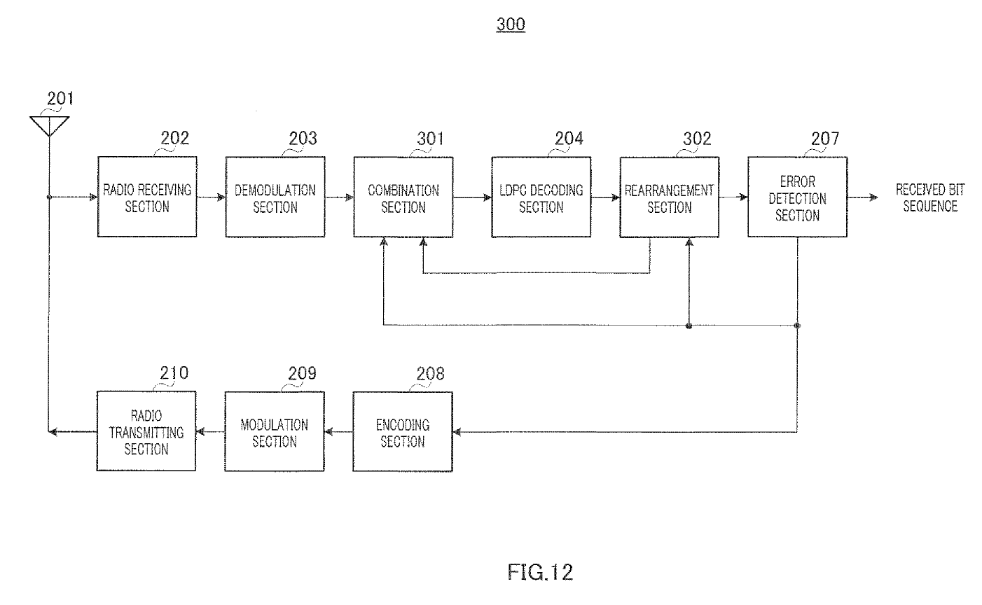

Next, the radio communication apparatus on the receiving side according to the present embodiment will be explained. FIG. 12 illustrates the configuration of radio communication apparatus 300 on the receiving side according to the present embodiment. In FIG. 12, the same components as in FIG. 7 will be assigned the same reference numerals and their explanation will be omitted. Furthermore, explanation of the same operations as in Embodiment 1 will be omitted.

Demodulation section 203 demodulates data symbols received as input from radio receiving section 202 to obtain received data and outputs the received data to combination section 301.

Upon receiving first transmission data (initial transmission data), combination section 301 pads padding bits having a logarithmic likelihood ratio of 0 in the received data according to the same rule as the transmission rule (FIG. 10) used in HARQ section 103 (FIG. 1), and stores and outputs the resulting data to LDPC decoding section 204.

On the other hand, upon receiving the second and subsequent transmission data (retransmission data), that is, upon receiving as input a NACK signal from error detection section 207, combination section 301 combines the received data, stored data and bit sequence received as input from rearrangement section 302, stores and outputs the resulting data LDPC decoding section 204.

Furthermore, upon receiving as input an ACK signal from error detection section 207, that is, when there is no error in the bit sequence received as input from rearrangement section 302, combination section 301 discards the stored data.

LDPC decoding section 204 performs LDPC decoding on the data received as input from combination section 301 based on the same parity check matrix as the parity check matrix used in LDPC encoding section 102 (FIG. 1), to obtain a decoded bit sequence. LDPC decoding section 204 then outputs the decoded bit sequence to rearrangement section 302.

Rearrangement section 302 rearranges the decoded bit sequence received as input from LDPC decoding section 204 according to the received data and outputs the result to error detection section 207. To be more specific, when the received data is an LDPC codeword A, rearrangement section 302 outputs the decoded bit sequence as is to error detection section 207, whereas, when the received data is an LDPC codeword B, rearrangement section 302 rearranges the decoded bit sequence and outputs the rearranged bit sequence to error detection section 207.

Furthermore, when a NACK signal is received as input from error detection section 207, that is, when retransmission data is received, rearrangement section 302 rearranges the decoded bit sequence received as input from LDPC decoding section 204 according to the next transmission data and outputs the result to combination section 301. To be more specific, when the next transmission data is an LDPC codeword A, rearrangement section 302 outputs the decoded bit sequence as is to combination section 301, whereas, when the next transmission data is an LDPC codeword B, rearrangement section 302 rearranges the decoded bit sequence and outputs the rearranged bit sequence to combination section 301.

Error detection section 207 performs an error detection on the bit sequence received as input from rearrangement section 302. Furthermore, error detection section 207 outputs a response signal generated (ACK signal or NACK signal) to combination section 301, rearrangement section 302 and encoding section 208.

Next, the operations of radio communication apparatus 300 on the receiving side having the above configuration will be explained.

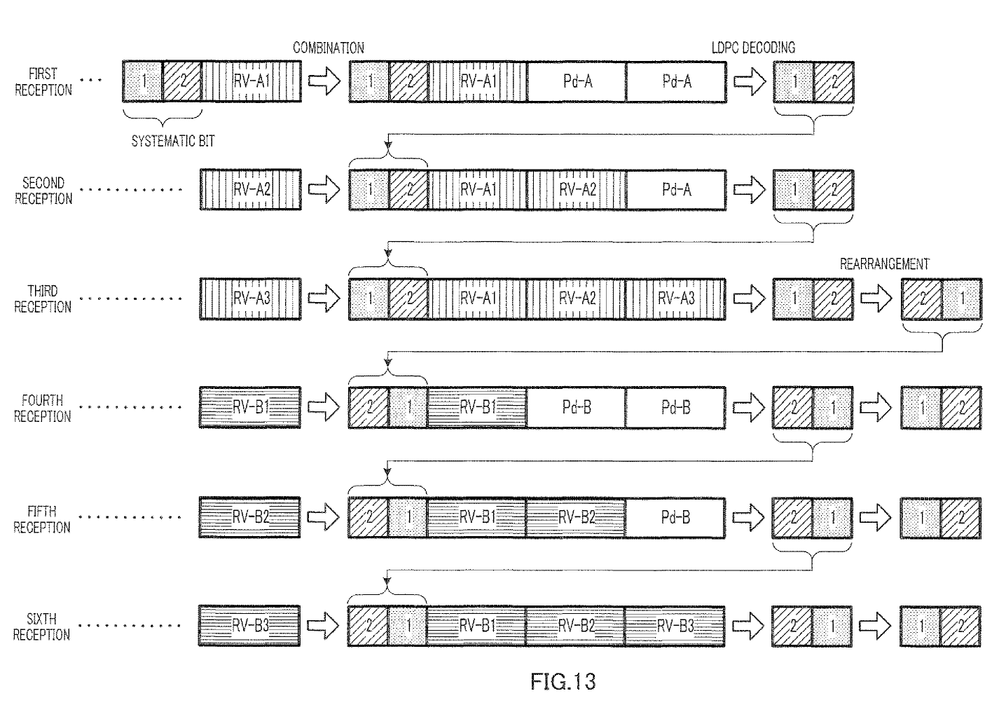

As shown in FIG. 13, upon receiving first transmission data (initial transmission data), combination section 301 identifies that bits of the received data are systematic bits of LDPC codeword A and parity bits comprising RV-A1, according to the transmission rule (FIG. 10). Combination section 301 then allocates the systematic bits to its corresponding systematic bit positions, and allocates the parity bits comprising RV-A1 to their corresponding parity bit positions. Combination section 301 then pads padding bits having a logarithmic likelihood ratio of 0 to the parity bit positions other than parity bit positions allocated bits, that is, to the parity bit positions corresponding to parity bits comprising RV-A2 and RV-A3 with. That is, as shown in FIG. 13, combination section 301 pads a bit sequence Pd-A comprised of padding bits corresponding to the number of parity bits comprising RV-A2 and RV-A3 after RV-A1 of the received data. By this means, it is possible to obtain data of the same data length as that of LDPC codeword A generated in radio communication apparatus 100 on the transmitting side. Therefore, upon receiving the first transmission data (initial transmission data), LDPC decoding section 204 performs LDPC decoding on the data comprised of bit sequence 1, bit sequence 2, RV-A1, Pd-A and Pd-A in order, to obtain a decoded bit sequence comprised of bit sequence 1 and bit sequence 2 in order. Error detection section 207 receives as input this decoded bit sequence without being rearranged by rearrangement section 302.

Next, upon receiving second transmission data (first retransmission data), as shown in FIG. 13, rearrangement section 302 outputs the decoded bit sequence, received as input upon receiving the first transmission data (initial transmission data), as is to combination section 301. Furthermore, combination section 301 identifies that the bits of the received data are parity bits comprising RV-A2 according to the transmission rule (FIG. 10). Combination section 301 then allocates the decoded bit sequence received as input from rearrangement section 302 to its corresponding systematic bit positions, combines parity bits comprising RV-A2 and padding bits comprising Pd-A and allocates the parity bits comprising RV-A2 to their corresponding parity bit positions. Therefore, upon receiving second transmission data (first retransmission data), LDPC decoding section 204 performs LDPC decoding on data comprised of bit sequence 1, bit sequence 2, RV-A1, RV-A2 and Pd-A in order, to obtain a decoded bit sequence comprised of bit sequence 1 and bit sequence 2 in order. Error detection section 207 receives as input this decoded bit sequence without being rearranged by rearrangement section 302.

Likewise, upon receiving third transmission data (second retransmission data), as shown in FIG. 13, rearrangement section 302 outputs the decoded bit sequence, received as input upon receiving the second transmission data (first retransmission data), as is to combination section 301. Furthermore, combination section 301 identifies that the bits of the received data are parity bits comprising RV-A3 according to the transmission rule (FIG. 10). Combination section 301 then allocates the decoded bit sequence received as input from rearrangement section 302 to its corresponding systematic bit positions, combines parity bits comprising RV-A3 and padding bits comprising Pd-A and allocates the parity bits comprising RV-A3 to their corresponding parity bit positions. Therefore, upon receiving third transmission data (second retransmission data), LDPC decoding section 204 performs LDPC decoding on the data comprised of bit sequence 1, bit sequence 2, RV-A1, RV-A2 and RV-A3 in order, to obtain a decoded bit sequence comprised of bit sequence 1 and bit sequence 2 in order. Error detection section 207 receives as input this decoded bit sequence without being rearranged by rearrangement section 302.

Next, upon receiving fourth transmission data (third retransmission data), rearrangement section 302 rearranges the decoded bit sequence received as input upon receiving the third transmission data (second retransmission data), in the reverse order as shown in FIG. 13, and outputs a bit sequence comprised of bit sequence 2 and bit sequence 1 in order, to combination section 301. Furthermore, combination section 301 identifies that the bits of the received data are parity bits comprising RV-B1 according to the transmission rule (FIG. 10). Combination section 301 then allocates the bit sequence received as input from rearrangement section 302 to its corresponding systematic bit positions and allocates the parity bits comprising RV-B1 to their corresponding parity bit positions. Combination section 301 then pads parity bits to parity bit positions other than the positions allocated bits, that is, to parity bit positions corresponding to the parity bits comprising RV-B2 and RV-B3. That is, as shown in FIG. 13, combination section 301 pads a bit sequence Pd-B comprised of padding bits corresponding to the number of the parity bits comprising RV-B2 and RV-B3, after RV-B1 of the received data. By this means, it is possible to obtain data of the same data length as that of LDPC codeword B generated in radio communication apparatus 100 on the transmitting side. Therefore, upon receiving fourth transmission data (third retransmission data), LDPC decoding section 204 performs LDPC decoding on the data comprised of bit sequence 2, bit sequence 1, RV-B1, Pd-B and Pd-B in order, to obtain a decoded bit sequence comprised of bit sequence 2 and bit sequence 1 in order. Rearrangement section 302 then rearranges the decoded bit sequence in the reverse order to obtain a bit sequence comprised of bit sequence 1 and bit sequence 2 in order, and outputs the bit sequence to error detection section 207.

Next, upon receiving fifth transmission data (fourth retransmission data), as shown in FIG. 13, rearrangement section 302 outputs the decoded bit sequence, received as input upon receiving the fourth transmission data (third retransmission data), as is to combination section 301. Furthermore, combination section 301 identifies that the bits of the received data are parity bits comprising RV-B2 according to the transmission rule (FIG. 10). Combination section 301 then allocates the decoded bit sequence received as input from rearrangement section 302 to its corresponding systematic bit positions, combines parity bits comprising RV-B2 and padding bits comprising Pd-B and allocates the parity bits comprising Pd-B2 to their corresponding parity bit positions. Therefore, upon receiving the fifth transmission data (fourth retransmission data), LDPC decoding section 204 performs LDPC decoding on the data comprised of bit sequence 2, bit sequence 1, RV-B1, RV-B2 and Pd-B in order, to obtain a decoded bit sequence comprised of bit sequence 2 and bit sequence 1 in order. Rearrangement section 302 then rearranges the decoded bit sequence in the reverse order to obtain a bit sequence comprised of bit sequence 1 and bit sequence 2 in order, and outputs the bit sequence to error detection section 207.

Likewise, upon receiving sixth transmission data (fifth retransmission data), as shown in FIG. 13, rearrangement section 302 outputs the decoded bit sequence, received as input upon receiving the fifth transmission data (fourth retransmission data), as is to combination section 301. Furthermore, combination section 301 identifies that the bits of the received data are parity bits comprising RV-B3 according to the transmission rule (FIG. 10). Combination section 301 then allocates the decoded bit sequence received as input from rearrangement section 302 to its corresponding systematic bit positions, combines parity bits comprising RV-B3 and padding bits comprising Pd-B and allocates the parity bits comprising RV-B3 to their corresponding parity bit positions. Therefore, upon receiving the sixth transmission data (fifth retransmission data), LDPC decoding section 204 performs LDPC decoding on the data comprised of bit sequence 2, bit sequence 1, RV-B1, RV-B2 and RV-B3 in order, to obtain a decoded bit sequence comprised of bit sequence 2 and bit sequence 1 in order. Rearrangement section 302 then rearranges the decoded bit sequence in the reverse order to obtain a bit sequence comprised of bit sequence 1 and bit sequence 2 in order and outputs the bit sequence to error detection section 207.

Thus, according to the present embodiment, when an LDPC codeword is used in HARQ of an IR scheme, the radio communication apparatus on the transmitting side transmits only parity bits of LDPC codeword B after all parity bits included in LDPC codeword A are transmitted. This allows the radio communication apparatus on the receiving side to preferentially provide the effect of likelihood improvement under the IR scheme for LDPC codeword A through a minimum number of transmissions.

Furthermore, according to the present embodiment, bits in which only small effects of likelihood improvement under the IR scheme have been obtained, that is, bits with small column degrees and small effects of likelihood improvement are rearranged to the systematic bit positions with large column degrees and large effects of likelihood improvement, and LDPC-decoded. This allows the likelihood of bits having small effects of likelihood improvement to be improved with high priority. Therefore, according to the present embodiment, it is possible to equalize the effects of likelihood improvement of all systematic bits and improve error rate performance of all systematic bits to a uniform level in the same way as in Embodiment 1.

Furthermore, according to the present embodiment, when performing LDPC decoding on second and subsequent transmission data (retransmission data), the radio communication apparatus on the receiving side uses the previously-obtained decoded bit sequence as systematic bits. This allows LDPC decoding to be performed using the updated likelihood of the previously-obtained decoded bit sequence. Therefore, the present embodiment can efficiently improve error rate performance.

Furthermore, according to the present embodiment, the radio communication apparatus on the receiving side can obtain systematic bits of LDPC codeword B by rearranging systematic bits of LDPC codeword A. Therefore, the radio communication apparatus on the transmitting side need not transmit systematic bits of LDPC codeword B, and can thereby improve transmission efficiency.

According to the present embodiment, although combination section 301 combines the bits of received data and padding bits, combination section 301 may also combine the bits of the received data and immediately earlier decoded likelihood.

### Embodiment 3

The present embodiment differs from Embodiment 2 in selecting an LDPC codeword to be transmitted according to the number of transmitted parity bits of an LDPC codeword A and the number of transmitted parity bits of an LDPC codeword B.

In HARQ of an IR scheme, when the number of RV transmissions increases and the number of parity bits transmitted to the radio communication apparatus on the receiving side increases, the effect of likelihood improvement by the RV's gradually decreases. That is, when the coding rate of transmitted data decreases sufficiently, the effect of likelihood improvement becomes less likely to be obtained even if further RV's are transmitted. Therefore, if the number of RV transmissions increases and the number of remaining RV's decreases, it is preferable to supplement the likelihood of bits having smaller effects of likelihood improvement by rearranging a transmission bit sequence to increase the likelihood of bits. That is, when the number of parity bits transmitted increases, the effect of likelihood improvement through rearrangement of the transmission bit sequence becomes high.

Thus, HARQ section 103 according to the present embodiment (FIG. 1) selects one of LDPC codeword A and LDPC codeword B according to the number of transmitted parity bits of LDPC codeword A and the number of transmitted parity bits of LDPC codeword B.

The present embodiment will be explained below in detail. Here, in LDPC codeword A shown in FIG. 9A and LDPC codeword B shown in FIG. 9B, the number of transmitted parity bits for reducing the coding rate of transmitted data to a sufficiently small value, is assumed to be ⅔ of the number of parity bits of each LDPC codeword. That is, when two of three RV's are transmitted, the coding rate of transmitted data is reduced to a sufficiently small value. Therefore, HARQ section 103 selects one of LDPC codeword A and LDPC codeword B according to the number of RV transmissions. Furthermore, the number of times a plurality of RV's of one LDPC codeword are transmitted consecutively (hereinafter referred to as “number of consecutive transmissions”) is assumed to be 2 and set in HARQ section 103. In the following explanation, the same operations as in Embodiment 2 will be omitted.

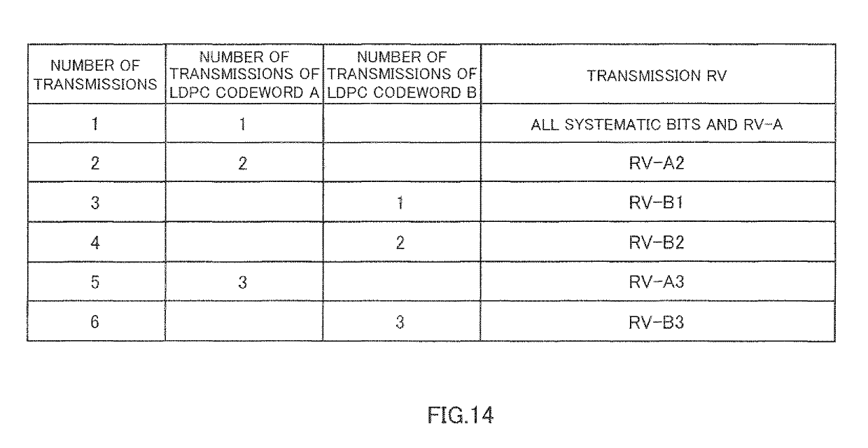

HARQ section 103 selects RV's according to a transmission rule shown in FIG. 14. To be more specific, HARQ section 103 selects RV-A1 and RV-A2 comprised of parity bits of LDPC codeword A at the first transmission (initial transmission) and second transmission (first retransmission), respectively. As shown in FIG. 14, the number of transmissions of LDPC codeword A reaches 2, and therefore HARQ section 103 selects RV-B1 and RV-B2 comprised of parity bits of LDPC codeword B at the third transmission (second retransmission) and fourth transmission (third retransmission), respectively. Likewise, as shown in FIG. 14, the number of transmissions of LDPC codeword B reaches 2, and therefore HARQ section 103 selects RV-A3 comprised of parity bits of LDPC codeword A at the fifth transmission (fourth retransmission). Furthermore, all RV's comprised of parity bits of LDPC codeword A have been selected, and therefore HARQ section 103 selects RV-B3 comprised of parity bits of LDPC codeword B at the sixth transmission (fifth retransmission).

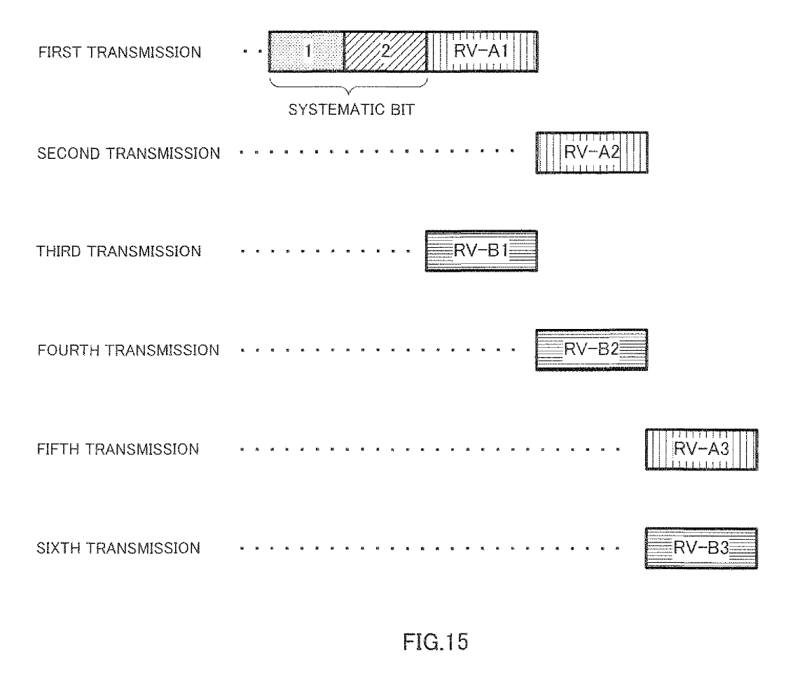

Therefore, as shown in FIG. 15, HARQ section 103 outputs an LDPC codeword comprised of systematic bits and RV-A1 to modulation section 104 at the first transmission (initial transmission) and outputs RV-A2 to modulation section 104 at the second transmission (first retransmission). Furthermore, HARQ section 103 outputs RV-B1 to modulation section 104 at the third transmission (second retransmission) and outputs RV-B2 to modulation section 104 at the fourth transmission (third retransmission). Furthermore, HARQ section 103 outputs RV-A3 to modulation section 104 at the fifth transmission (fourth retransmission) and outputs RV-B3 to modulation section 104 at the sixth transmission (fifth retransmission).

Furthermore, combination section 301 of radio communication apparatus 300 on the receiving side (FIG. 12) identifies received bits in the same way as in Embodiment 2 according to the same rule as the transmission rule used in HARQ section 103 (FIG. 14), and allocates the identified received bits to their corresponding bit positions.

Thus, when the number of RV transmissions increases and the effect of likelihood improvement of an IR scheme becomes less likely to be obtained, the present embodiment improves the likelihood of bits with smaller effects of likelihood improvement by rearranging the transmission bit sequence. This makes it possible to efficiency achieve both the effect of likelihood improvement under the IR scheme and effect of likelihood improvement through rearrangement of the transmission bit sequence simultaneously. Therefore, according to the present embodiment, it is possible to provide effects similar to those in Embodiment 2 through a smaller number of RV transmissions.

Although a case has been explained with the present embodiment where the number of consecutive transmissions set in HARQ section 103 is 2, the number of consecutive transmissions may also be set to 1 or 3 or more. Furthermore, the number of consecutive transmissions is not limited to a fixed number. For example, HARQ section 103 may reduce the number of consecutive transmissions when the number of RV transmissions increases. By this means, when the number of RV transmissions is small, it is possible to provide the effect of likelihood improvement through IR of the same LDPC codeword preferentially, while, when the number of RV transmissions is large, it is possible to provide the effect of likelihood improvement through rearrangement preferentially. Furthermore, LDPC codewords may also be selected according to the coding rate of transmitted data. For example, when the coding rate of transmitted data of one LDPC codeword is equal to or less than a predetermined threshold, HARQ section 103 may select the other LDPC codeword.

### Embodiment 4

The present embodiment differs from Embodiment 2 in, upon receiving second and subsequent transmission data (retransmission data), performing LDPC decoding using systematic bits of LDPC codeword A received upon receiving first transmission data (initial data).

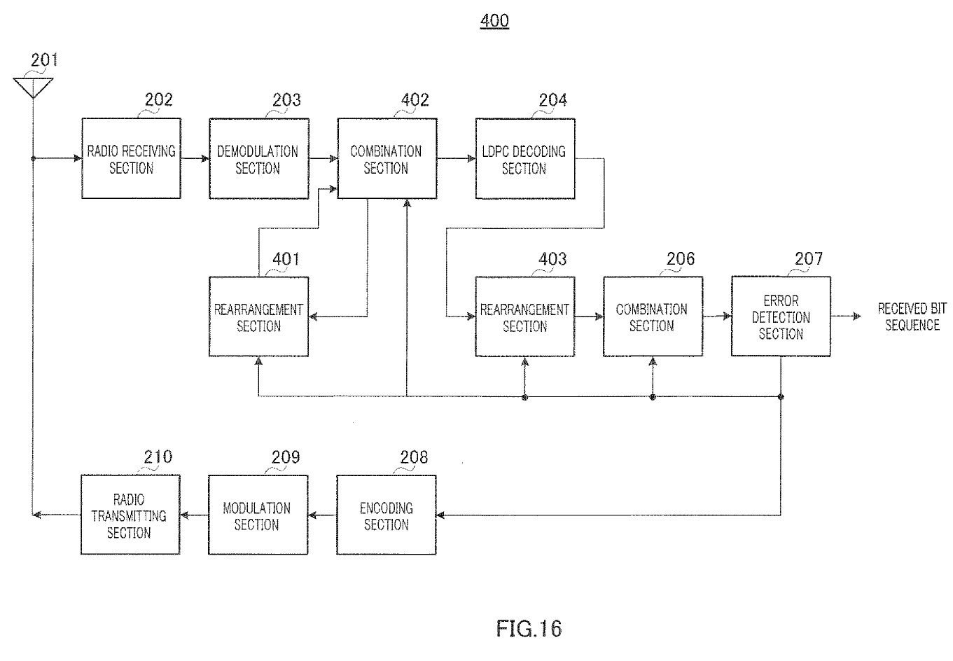

A radio communication apparatus on the receiving side according to the present embodiment will be explained. FIG. 16 shows the configuration of radio communication apparatus 400 on the receiving side according to the present embodiment. In FIG. 16, the same components as in FIG. 7 will be assigned the same reference numerals and their explanation will be omitted. Furthermore, explanation of the same operations as in Embodiment 2 will be omitted.

Upon receiving first transmission data (initial transmission data), combination section 402 pads padding bits having a logarithmic likelihood ratio of 0 in received data according to the same rule as the transmission rule used in HARQ section 103 of radio communication apparatus 100 on the transmitting side (FIG. 1), and stores and outputs the resulting data to LDPC decoding section 204. Furthermore, combination section 402 outputs systematic bits of the received data to rearrangement section 401.

On the other hand, upon receiving second and subsequent transmission data (retransmission data), that is, upon receiving as input a NACK signal from error detection section 207, combination section 402 combines the received data and stored data if the received data is an LDPC codeword A, and combines the received data, stored data and the bit sequence received as input from rearrangement section 401 if the received data is an LDPC codeword B. Combination section 402 stores and outputs the resulting data to LDPC decoding section 204.

Furthermore, upon receiving as input an ACK signal from error detection section 207, that is, when there is no error in the bit sequence received as input in error detection section 207, combination section 402 discards the stored data.

Upon receiving as input a NACK signal from error detection section 207, that is, upon receiving retransmission data, if next transmission data is LDPC codeword B, rearrangement section 401 rearranges systematic bits received as input from combination section 402 and outputs the rearranged bit sequence to combination section 402.

Rearrangement section 403 receives as input a response signal from error detection section 207. According to the same rule as the transmission rule used in HARQ section 103 of radio communication apparatus 100 on the transmitting side (FIG. 1), when the received data is LDPC codeword A, rearrangement section 403 outputs the decoded bit sequence as is to combination section 206, while, when the received data is LDPC codeword B, rearrangement section 403 rearranges the decoded bit sequence and outputs the rearranged bit sequence to combination section 206.

Error detection section 207 performs an error detection on the combined bit sequence received as input from combination section 206. Furthermore, error detection section 207 outputs a response signal generated (ACK signal or NACK signal) to combination section 206, combination section 402, rearrangement section 401, rearrangement section 403 and encoding section 208.

Next, the operations of radio communication apparatus 400 on the receiving side having the above configuration will be explained. Here, suppose radio communication apparatus 100 on the transmitting side (FIG. 1) follows the transmission rule shown in FIG. 10 in the same way as in Embodiment 2. Explanation of the same operations as in Embodiment 2 shown in FIG. 13 will be omitted below.

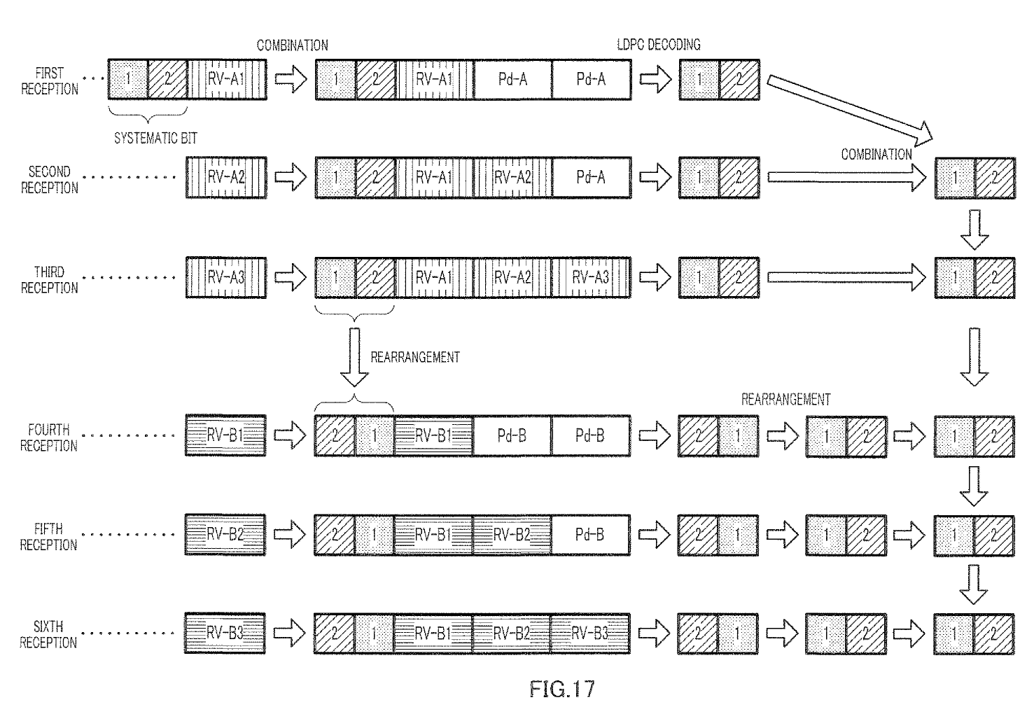

Upon receiving second transmission data (first retransmission data), as shown in FIG. 17, combination section 402 combines parity bits comprising RV-A2 and padding bits comprising Pd-A, and allocates the parity bits comprising RV-A2 to their corresponding parity bit positions. LDPC decoding section 204 obtains a decoded bit sequence comprised of bit sequence 1 and bit sequence 2 in order. Combination section 206 receives as input this decoded bit sequence without being rearranged by rearrangement section 403. As shown in FIG. 17, combination section 206 combines the decoded bit sequence obtained upon receiving second transmission data (first retransmission data) and the decoded bit sequence obtained upon receiving the first transmission data (initial transmission data) to generate a combined bit sequence.

Likewise, upon receiving third transmission data (second retransmission data), as shown in FIG. 17, combination section 402 combines parity bits comprising RV-A3 and padding bits comprising Pd-A, and allocates the parity bits comprising RV-A3 to their corresponding parity bit positions. LDPC decoding section 204 obtains a decoded bit sequence comprised of bit sequence 1 and bit sequence 2 in order. Combination section 206 receives as input this decoded bit sequence without being rearranged by rearrangement section 403. As shown in FIG. 17, combination section 206 combines the decoded bit sequence obtained upon receiving third transmission data (second retransmission data) and the combined bit sequence generated upon receiving second transmission data (first retransmission data) to generate a new combined bit sequence.

Next, upon receiving fourth transmission data (third retransmission data), as shown in FIG. 17, rearrangement section 401 rearranges the combined bit sequence received as input from combination section 402, that is, the systematic bit sequence comprised of bit sequence 1 and bit sequence 2 in order in the reverse order, and outputs the bit sequence comprised of bit sequence 2 and bit sequence 1 in order, to combination section 402. Combination section 402 allocates the bit sequence received as input from rearrangement section 401 to its corresponding systematic bit positions, and allocates parity bits comprising RV-B1 to their corresponding parity bit positions. LDPC decoding section 204 obtains a decoded bit sequence comprised of bit sequence 2 and bit sequence 1 in order. Furthermore, rearrangement section 302 rearranges the decoded bit sequence in the reverse order to obtain a bit sequence comprised of bit sequence 1 and bit sequence 2 in order. As shown in FIG. 17, combination section 206 combines the bit sequence obtained upon receiving fourth transmission data (third retransmission data) and the combined bit sequence generated upon receiving the third transmission data (second retransmission data) to obtain a new combined bit sequence.

Likewise, as shown in FIG. 17, upon receiving fifth transmission data (fourth retransmission data), combination section 402 combines parity bits comprising RV-B2 and padding bits comprising Pd-B, and allocates the parity bits comprising RV-B2 to their corresponding parity bit positions. LDPC decoding section 204 obtains a decoded bit sequence comprised of bit sequence 2 and bit sequence 1 in order. Furthermore, rearrangement section 302 rearranges the decoded bit sequence in the reverse order to obtain a bit sequence comprised of bit sequence 1 and bit sequence 2 in order. As shown in FIG. 17, combination section 206 combines the bit sequence obtained upon receiving the fifth transmission data (fourth retransmission data) and the combined bit sequence generated upon receiving the fourth transmission data (third retransmission data) to generate a new combined bit sequence.

Furthermore, as shown in FIG. 17, upon receiving sixth transmission data (fifth retransmission data), combination section 402 combines parity bits comprising RV-B3 and padding bits comprising Pd-B, and allocates the parity bits comprising RV-B3 to their corresponding parity bit positions. LDPC decoding section 204 obtains a decoded bit sequence comprised of bit sequence 2 and bit sequence 1 in order. Furthermore, rearrangement section 302 rearranges the decoded bit sequence in the reverse order to obtain a bit sequence comprised of bit sequence 1 and bit sequence 2 in order. As shown in FIG. 17, combination section 206 combines the bit sequence obtained upon receiving the sixth transmission data (fifth retransmission data) and the combined bit sequence generated upon receiving the fifth transmission data (fourth retransmission data) to generate a new combined bit sequence.

Thus, according to the present embodiment, the radio communication apparatus on the receiving side combines a decoded bit sequence generated every time an RV is received and a previously stored bit sequence, so that it is possible to further improve likelihood through the combination in addition to the effect of likelihood improvement through RV retransmissions of an IR scheme. Furthermore, according to the present embodiment, by supplementing the likelihood of bits with smaller effects of likelihood improvement under the IR scheme through rearrangement of the transmission bit sequence in the same way as in Embodiment 2, it is possible to equalize the effect of likelihood improvement of all systematic bits and improve error rate performance of all systematic bits to a uniform level. Therefore, according to the present embodiment, even when LDPC decoding is performed using systematic bits of first transmission data (initial transmission data) upon receiving second and subsequent transmission data (retransmission data), it is possible to always obtain optimum error rate performance.

Furthermore, according to the present embodiment, the radio communication apparatus on the receiving side rearranges systematic bits of LDPC codeword A, and can thereby obtain systematic bits of LDPC codeword B. Therefore, the radio communication apparatus on the transmitting side need not transmit systematic bits of LDPC codeword B, and can thereby improve transmission efficiency.

The embodiments of the present invention have been explained so far.

Although a case has been explained with the above described embodiments where a transmission bit sequence is rearranged, the present invention may also rearrange each column of a parity check matrix instead of rearranging the transmission bit sequence. Even by performing LDPC encoding on the transmission bit sequence based on the parity check matrix after rearrangement, it is possible to provide similar effects.

Although a case has been explained with the above embodiments where a transmission bit sequence is rearranged once and one of LDPC codeword A and LDPC codeword B is transmitted, the present invention may also rearrange the transmission bit sequence twice or more and transmit one of three or more different LDPC codewords.

Furthermore, although a case has been explained with the above described embodiments where a transmission bit sequence is rearranged according to column degrees of a parity check matrix, the present invention may also randomly rearrange the transmission bit sequence. Even by rearranging the transmission bit sequence randomly, it is possible to averagely give the effect of likelihood improvement, which varies depending on column degrees, to each bit of the transmission bit sequence in the same way as in the above embodiments. Furthermore, the rearrangement section may also be comprised of a channel interleaves, thereby reducing the circuit scale of the rearrangement section.

Furthermore, the parity check matrix shown in FIG. 2 is an example and the parity check matrix usable for implementation of the present invention is not limited to the parity cheek matrix shown in FIG. 2. For example, a parity check matrix which varies depending on the data size or coding rate of the transmission bit sequence may also be used.

Furthermore, in the above embodiments, although the number of transmissions of LDPC codewords is associated with an LDPC codeword selected in advance using a transmission rule, the present invention is also applicable to a case where the number of transmissions of LDPC codewords is not associated with an LDPC codeword selected in advance. For example, the radio communication apparatus on the transmitting side can arbitrarily select an LDPC codeword to be transmitted if the radio communication apparatus on the transmitting side reports which LDPC codeword has been transmitted, to the radio communication apparatus on the receiving side via a control channel.

Furthermore, although the operations to transmit all bits included in LDPC codeword A and LDPC codeword B have been explained with the above described embodiments, when data is further retransmitted, it is possible to return to the operation of the first transmission (initial transmission) and perform a retransmission.

Furthermore, although a case has been explained with the above described embodiments where a transmission bit sequence is rearranged in advance and LDPC codewords are stored, it is also possible to store the transmission bit sequence and rearrange the transmission bit sequence for every data transmission.

Furthermore, in a mobile communication system, radio communication apparatus 100 on the transmitting side may be provided in a radio communication base station apparatus and radio communication apparatus 200, 300 or 400 on the receiving side may be provided in a radio communication mobile station apparatus. Furthermore, radio communication apparatus 100 on the transmitting side may be provided in the radio communication mobile station apparatus and radio communication apparatus 200, 300 or 400 on the receiving side may be provided in the radio communication base station apparatus. This makes it possible to realize a radio communication base station apparatus and radio communication mobile station apparatus that provide the similar operations and effects to the above.

Furthermore, a radio communication mobile station apparatus may also be referred to as a “UE” and a radio communication base station apparatus may also be referred to as “Node B.”

Furthermore, the variable node may also be referred to as “bit node.”

Furthermore, the present invention is applicable to any of type 1 HARQ (HARQ-type1), type 2 HARQ (HARQ-type2) and type 3 HARQ (HARQ-type3).

Although a case has been described with the above embodiments as an example where the present invention is implemented with hardware, the present invention can be implemented with software.

Furthermore, each function block employed in the description of each of the aforementioned embodiments may typically be implemented as an LSI constituted by an integrated circuit. These may be individual chips or partially or totally contained on a single chip. “LSI” is adopted here but this may also be referred to as “IC,” “system LSI,” “super LSI,” or “ultra LSI” depending on differing extents of integration.

Further, the method of circuit integration is not limited to LSI's, and implementation using dedicated circuitry or general purpose processors is also possible. After LSI manufacture, utilization of an FPGA (Field Programmable Gate Array) or a reconfigurable processor where connections and settings of circuit cells in an LSI can be reconfigured is also possible.

Further, if integrated circuit technology comes out to replace LSI's as a result of the advancement of semiconductor technology or a derivative other technology, it is naturally also possible to carry out function block integration using this technology. Application of biotechnology is also possible.

The disclosure of Japanese Patent Application No. 2007-108572, filed on Apr. 17, 2007, including the specification, drawings and abstract, is incorporated herein by reference in its entirety.

### INDUSTRIAL APPLICABILITY

The present invention is applicable to a mobile communication system or the like.

1. A radio communication apparatus on a transmitting side, comprising:
a rearrangement section that rearranges a first bit sequence to generate a second bit sequence;
an encoding section that performs LDPC encoding using a parity check matrix on the first bit sequence to obtain a first codeword and performs the LDPC encoding using the parity check matrix on the second bit sequence to obtain a second codeword; and
a selection section that selects one of the first codeword and the second codeword.

2. The radio communication apparatus according to claim 1, wherein the rearrangement section generates the second bit sequence by allocating bits of systematic bit positions with small column degrees of the parity check matrix in the first bit sequence, to systematic bit positions with large column degrees.

3. The radio communication apparatus according to claim 1, wherein the selection section selects the second codeword after all parity bits included in the first codeword are transmitted.

4. The radio communication apparatus according to claim 1, wherein, when the second codeword is transmitted, the selection section selects only parity bits of the second codeword.

5. The radio communication apparatus according to claim 1, wherein the selection section selects one of the first codeword and the second codeword according to the number of transmitted parity bits of the first codeword and the number of transmitted parity bits of the second codeword.

6. A radio communication apparatus on a receiving side, comprising:
a receiving section that receives one of a first codeword obtained by performing LDPC encoding using a parity check matrix on a first bit sequence and a second codeword obtained by performing the LDPC encoding using the parity check matrix on a second bit sequence generated by rearranging the first bit sequence;
a decoding section that performs LDPC decoding using the parity cheek matrix on a received codeword to obtain a first received bit sequence; and
a rearrangement section that rearranges the first received bit sequence to generate a second received bit sequence.

7. The radio communication apparatus according to claim 6, further comprising a combination section that combines the second received bit sequence and the previously obtained first received bit sequence to obtain a combined bit sequence.

8. The radio communication apparatus according to claim 6, further comprising an arrangement section that identifies received bits comprising a received codeword, allocates the identified received bits and bits of the previously obtained second received bit sequence to their corresponding bit positions, and generates received data,
wherein the decoding section performs the LDPC decoding using the parity check matrix on the received data to obtain the first received bit sequence.

9. A radio communication method comprising:
a rearranging step of rearranging a first bit sequence to generate a second bit sequence;
an encoding step of performing LDPC encoding using a parity check matrix on the first bit sequence to obtain a first codeword and performing the LDPC encoding using the parity check matrix on the second bit sequence to obtain a second codeword; and
a selecting step of selecting one of the first codeword and the second codeword.
